(19) United States
(12) Patent Application Publication
(10) Pub. No.: US 2024/0096861 A1
(43) Pub. Date: Mar. 21, 2024

(54) SEMICONDUCTOR PACKAGE ASSEMBLY

(71) Applicant: MEDIATEK INC., Hsinchu City (TW)

(72) Inventors: Che-Hung KUO, Hsinchu City (TW); Hsiao-Yun CHEN, Hsinchu City (TW); Wen-Pin CHU, Hsinchu City (TW); Chun-Hsiang HUANG, Hsinchu City (TW)

(21) Appl. No.: 18/454,220

(22) Filed: Aug. 23, 2023

Related U.S. Application Data
(60) Provisional application No. 63/376,306, filed on Sep. 20, 2022.

(51) Int. Cl. H01L 25/10; H01L 23/31; H01L 23/48; H01L 23/538; H10B 80/00

(52) U.S. Cl. CPC H01L 25/105; H01L 23/3128; H01L 23/481; H01L 23/5383; H01L 23/5385; H01L 28/90; H10B 80/00; H01L 24/16; H01L 2224/16225

(57) ABSTRACT

A semiconductor package assembly is provided. The semiconductor package assembly includes first semiconductor die, a second semiconductor die and a memory package. The first semiconductor die and the second semiconductor die are stacked on each other. The first semiconductor die includes a first interface and a third interface. The first interface overlaps and is electrically connected to the second interface arranged on the second semiconductor die. The third interface is arranged on a first edge of the first semiconductor die. The memory package is disposed beside the first semiconductor die, wherein the memory package is electrically connected to the first semiconductor die by the third interface.

### CROSS REFERENCE TO RELATED APPLICATIONS

This application claims the benefit of U.S. Provisional Application No. 63/376,306, filed Sep. 20, 2022, the entirety of which is incorporated by reference herein.

### BACKGROUND OF THE INVENTION

### Field of the Invention

The present invention relates to a semiconductor package assembly, and, in particular, to an interface floorplan for a package-on-package (PoP) semiconductor package.

### Description of the Related Art

With the increased demand for smaller devices with more functionality, package-on-package (PoP) technology has become increasingly popular. PoP technology vertically stacks two or more packages and minimizes the track lengths between different components, such as a controller and a memory device. This provides better electrical performance, since shorter routing of interconnections yields faster signal propagation and reduced noise and cross-talk defects.

Although existing semiconductor package assemblies are generally adequate, they are not satisfactory in every respect. For example, it is challenging to fulfill the channel requirements for integrating different components into a package. Therefore, there is a need to further improve semiconductor package assemblies to provide flexibility in channel design.

### BRIEF SUMMARY OF THE INVENTION

An embodiment of the present invention provides a semiconductor package assembly. The semiconductor package assembly includes first semiconductor die, a second semiconductor die and a memory package. The first semiconductor die and the second semiconductor die are stacked on each other. The first semiconductor die includes a first interface and a third interface. The first interface overlaps and is electrically connected to a second interface arranged on the second semiconductor die. The third interface is arranged on a first edge of the first semiconductor die. The memory package is disposed beside the first semiconductor die, wherein the memory package is electrically connected to the first semiconductor die by the third interface.

An embodiment of the present invention provides a semiconductor package assembly. The semiconductor package assembly includes a fan-out package. The fan-out package includes a memory package, a first semiconductor die and a second semiconductor die. The first semiconductor die is arranged beside the memory package along a first direction. The second semiconductor die is arranged beside the memory package along a second direction. The first semiconductor die includes a first interface and a third interface. The first interface overlaps and is electrically connected to a second interface arranged on the second semiconductor die. The third interface is arranged close to and electrically connected to the memory package.

In addition, an embodiment of the present invention provides a semiconductor package assembly. The semiconductor package assembly includes a fan-out package. The fan-out package includes a first redistribution layer (RDL) structure, a second redistribution layer (RDL) structure, a top semiconductor die, a memory package and a bottom semiconductor die. The first redistribution layer (RDL) structure and the second redistribution layer (RDL) structure are stacked on each other. The top semiconductor die and the memory package are disposed on the first redistribution layer (RDL) structure. The top semiconductor die includes a first interface. The bottom semiconductor die is disposed between the first RDL structure and the second RDL structure. The bottom semiconductor die includes a second interface and first through via (TV) interconnects. The second interface overlaps the first interface. The first through via (TV) interconnects are arranged within the second interface and electrically connected to the first interface by the first RDL structure. The memory package is electrically connected to the top semiconductor die and the bottom semiconductor die by the first RDL structure rather than the second RDL structure.

### BRIEF DESCRIPTION OF THE DRAWINGS

The present invention can be more fully understood by reading the subsequent detailed description and examples with references made to the accompanying drawings, wherein:

FIG. 1A is a cross-sectional view of a semiconductor package assembly in accordance with some embodiments of the disclosure;

FIGS. 1B and 1C are perspective bottom views of a fan-out package of the semiconductor package assembly of FIG. 1A in accordance with some embodiments of the disclosure, showing the arrangement of interfaces of top and bottom semiconductor dies and through via (TV) interconnects of the bottom semiconductor die;

FIG. 2A is a cross-sectional view of a semiconductor package assembly in accordance with some embodiments of the disclosure;

FIGS. 2B, 2C and 2D are perspective bottom views of a fan-out package of the semiconductor package assembly of FIG. 2A in accordance with some embodiments of the disclosure, showing the arrangement of interfaces of top and bottom semiconductor dies and through via (TV) interconnects of the bottom semiconductor die;

FIG. 2E is an enlarge plan view of the bottom semiconductor die of the fan-out package of the semiconductor package assembly of FIG. 2A in accordance with some embodiments of the disclosure, showing the arrangement of through via (TV) interconnects of the bottom semiconductor die;

FIG. 3A is a cross-sectional view of a semiconductor package assembly in accordance with some embodiments of the disclosure;

FIG. 3B is a perspective bottom view of a fan-out package of the semiconductor package assembly of FIG. 3A in accordance with some embodiments of the disclosure, showing the arrangement of interfaces of top and bottom semiconductor dies, through via (TV) interconnects of the bottom semiconductor die and conductive structures of the semiconductor package assembly;

FIG. 4 is a cross-sectional view of a semiconductor package assembly in accordance with some embodiments of the disclosure;

FIG. 5 is a cross-sectional view of a semiconductor package assembly in accordance with some embodiments of the disclosure; and

FIG. 6 is an enlarge cross-sectional view of a semiconductor package assembly in accordance with some embodiments of the disclosure showing a trench capacitor embedded in a bottom semiconductor die of a fan-out package of the semiconductor package assembly of FIGS. 4 and 5.

### DETAILED DESCRIPTION OF THE INVENTION

The following description is made for the purpose of illustrating the general principles of the invention and should not be taken in a limiting sense. The scope of the invention is best determined by reference to the appended claims.

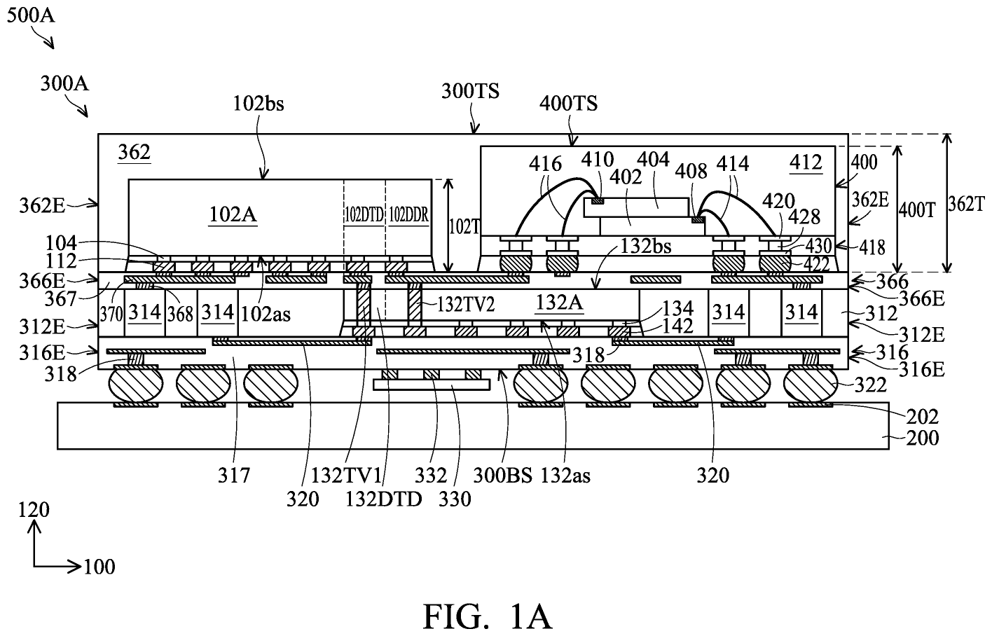

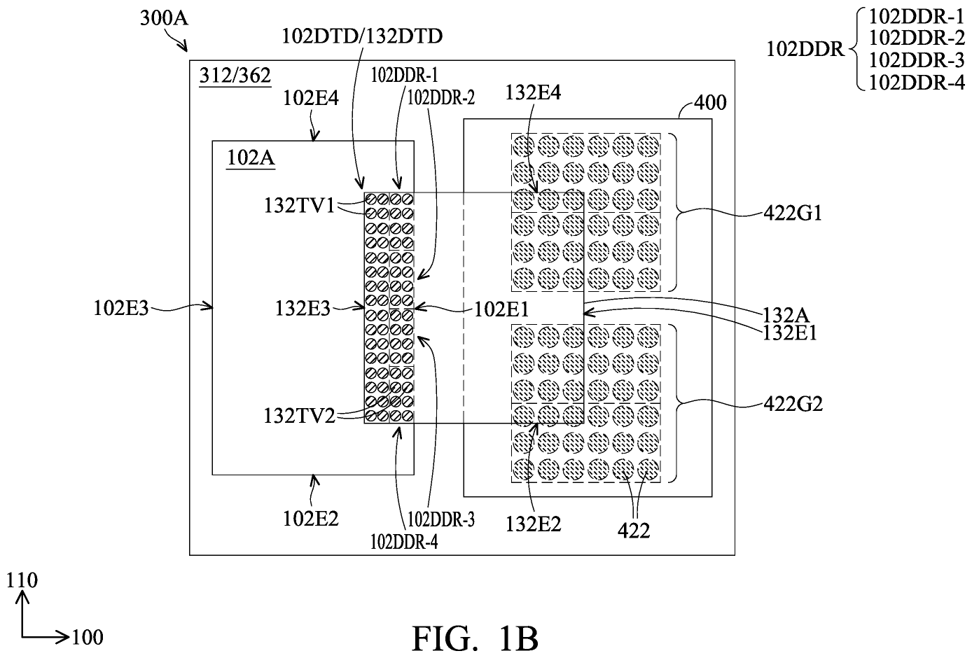

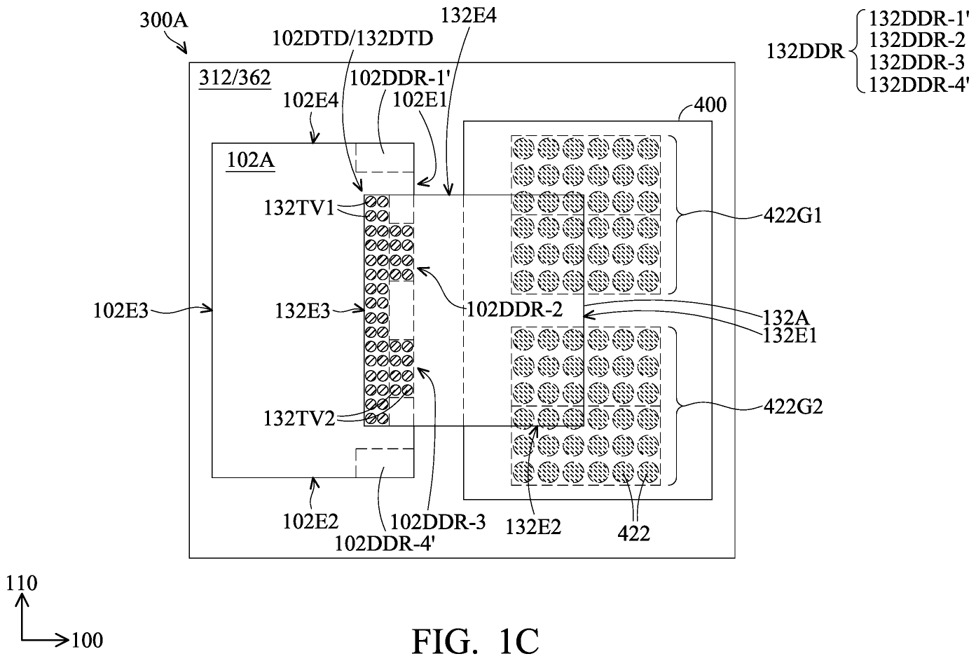

FIG. 1A is a cross-sectional view of a semiconductor package assembly 500A in accordance with some embodiments of the disclosure. FIGS. 1B and 1C are perspective bottom views (plan views) of a fan-out package 300A of the semiconductor package assembly 500A of FIG. 1A in accordance with some embodiments of the disclosure, showing the arrangement of interfaces of semiconductor dies 102A and 132A and through via (TV) interconnects 132TV1 and 132TV2 of the semiconductor die 132A. In some embodiments, the semiconductor package assembly 500A is a three-dimensional (3D) chiplet package assembly. The semiconductor package assembly 500A may include a wafer-level semiconductor package such as the fan-out package 300A including at least two vertically stacked semiconductor dies 102A and 132A and a memory package 400 mounted on a base 200.

As shown in FIG. 1A, the base 200, for example a printed circuit board (PCB), may be formed of polypropylene (PP), Pre-preg, FR-4 and/or other epoxy laminate material. It should also be noted that the base 200 can be a single layer or a multilayer structure. A plurality of pads 202 and/or conductive traces (not shown) is disposed on the base 200. In one embodiment, the conductive traces may comprise signal trace segments or ground trace segments, which are used for the input/output (I/O) connections of the fan-out package 300A. Also, the fan-out package 300A is mounted directly on the conductive traces. In some other embodiments, the pads 202 are disposed on the base 200, connected to different terminals of the conductive traces. The pads 202 are used for the fan-out package 300A that is mounted directly on them.

As shown in FIG. 1A, the fan-out package 300A is mounted on the base 200 by a bonding process. The fan-out package 300A is mounted on the base 200 using conductive structures 322. The fan-out package 300A is a three-dimensional (3D) semiconductor package including the semiconductor die 102A and 132A, redistribution layer (RDL) structures 316 and 366, molding compounds 312 and 362, through via (TV) interconnects 314 and the conductive structures 322. The conductive structures 322 are in contact with and electrically connected to the RDL structure 316. In addition, the conductive structures 322 are electrically connected to the base 200. In some embodiments, the conductive structures 322 comprise a conductive ball structure such as a copper ball, a conductive bump structure such as a copper bump or a solder bump structure, or a conductive pillar structure such as a copper pillar structure.

In some embodiments, the fan-out package 300A uses a chiplet architecture to split a large, single semiconductor die into multiple smaller functional semiconductor dies (called chiplets) fabricated in different technology nodes. Each chiplet may have improved device performance and fabrication yields. In addition, the fan-out package 300A may have a reduced fabrication cost. As shown in FIG. 1A, the fan-out package 300A includes at least two semiconductor dies, for example, the semiconductor die 102A and 132A (also called chiplets 102A and 132A) stacked on each other along the direction 120 (e.g., a vertical direction). The semiconductor die 102A is disposed on the RDL structure 366 and arranged side-by-side with the memory package 400 along a direction 100 (e.g., a lateral direction) that is different from the direction 120. The semiconductor die 132A is disposed between the RDL structures 316 and 366 and partially overlaps the semiconductor die 102 and the memory package 400 along the direction 120. Since the semiconductor die 102A and the semiconductor die 132A are respectively close to a top surface 300TS and a bottom surface 300BS of the fan-out package 300A, the semiconductor die 102A and the semiconductor die 132A may be also called a top semiconductor die 102A and a bottom semiconductor die 132A.

The semiconductor die 102A has an active surface 102as and a backside surface 102bs opposite to the active surface 102as. The semiconductor die 132A has an active surface 132as and a backside surface 132bs opposite to the active surface 132as. In some embodiments, the semiconductor die 102A and the semiconductor die 132A are fabricated by a flip-chip technology. The semiconductor die 102A may be flipped to be disposed on RDL structure 366 opposite the semiconductor die 132A. In addition, the semiconductor die 132A may be flipped to be disposed on the RDL structure 316 opposite the conductive structures 322. In some embodiments, the semiconductor dies 102A and 132A each independently includes a system-on-chip (SoC) die, a logic device, a memory device, a radio frequency (RF) device, the like, or any combination thereof. For example, the semiconductor die 102A and the semiconductor die 132A may each independently include a micro control unit (MCU) die, a microprocessor unit (MPU) die, a power management integrated circuit (PMIC) die, a global positioning system (GPS) device, a central processing unit (CPU) die, a graphics processing unit (GPU) die, an input-output (TO) die, a dynamic random access memory (DRAM) IP core, a static random-access memory (SRAM), a high bandwidth memory (HBM), the like, or any combination thereof. In some embodiments, the semiconductor dies 102A and 132A have different functions.

In some embodiments, the semiconductor die 132A further includes through via (TV) interconnects 132TV1 and 132TV2 formed passing through the semiconductor die 132A. Therefore, the semiconductor die 132A may be also called a TV die 132A. The TV interconnects 132TV1 and 132TV2 may be exposed form the backside surface 132bs of the semiconductor die 132A. In addition, the TV interconnects 132TV1 and 132TV2 have substantially vertical sidewalls and extend from the top surface of the active surface 132as and the backside surface 132bs of the semiconductor die 132A, but the present disclosure is not limit thereto. The TV interconnects 132TV1 and 132TV2 in the semiconductor die 132A may have other configurations and numbers. In some embodiments, the TV interconnects 132TV1 and 132TV2 may be formed of conductive material, such as a metal. For example, the TV interconnects 132TV1 and 132TV2 may be formed of copper.

The semiconductor dies 102A and 132A may be fabricated in different technology nodes. In some embodiments, the semiconductor die 102A has a first critical dimension (CD) and the semiconductor die 132A has a second critical dimension different from the first critical dimension in order to provide different functionalities with a reduced cost. For example, the first critical dimension is narrower than the second critical dimension. Therefore, the semiconductor dies 102A and 132A may respectively arrange various interfaces to fulfill the requirements of internal and external signal transmission of the fan-out package 300A.

The RDL structure 316 is disposed on the active surface 132as of the semiconductor die 132A. In other words, the semiconductor die 132A is disposed on the RDL structure 316. In addition, the RDL structure 316 is disposed between the semiconductor die 132A and the base 200 along the direction 120. Pads 134 on the active surface 132as of the semiconductor die 132A are electrically connected to the RDL structure 316 using conductive structures 142. In some embodiments, the conductive structures 142 include conductive materials, such as metal. The conductive structures 142 may include microbumps, controlled collapse chip connection (C4) bumps, ball grid array (BGA) balls, the like, or a combination thereof. As shown in FIG. 1A, the RDL structure 316 may include one or more conductive traces 320 and one or more vias 318 disposed in one or more dielectric layers 317. In some embodiments, the conductive traces 320 and the vias 318 include a conductive material, such as metals comprising copper, gold, silver, or other applicable metals. The dielectric layers 317 may include extra-low K (ELK) dielectrics and/or ultra-low K (ULK) dielectric. In addition, the dielectric layers 317 may include epoxy. The semiconductor die 132A is electrically connected to the base 200 using the vias 318 and the conductive traces 320 of the RDL structure 316 and the corresponding conductive structures 322. It should be noted that the number of vias 318, the number of conductive traces 320 and the number of dielectric layers 317 shown in FIG. 1A are only an example and is not a limitation to the present invention.

The through via (TV) interconnects 314 are disposed on the RDL structure 316 and beside the semiconductor die 132A. As shown in FIG. 1A, the TV interconnects 314 are electrically connected to the vias 318 and the conductive traces 320 of the RDL structure 316. In some embodiments, the TV interconnects 314 are electrically connected to the semiconductor die 132A using the vias 318 and the conductive traces 320 inside the RDL structure 316.

As shown in FIG. 1A, the molding compound 312 is disposed on and in contact with the RDL structure 316. The molding compound 312 surrounds and is in contact with the semiconductor die 132A and the TV interconnects 314. In addition, the TV interconnects 314 pass through the molding compound 312. The backside surface 132bs of the second semiconductor die 132A may be exposed from the molding compound 312. In some embodiments, the molding compound 312 may be formed of a nonconductive material, such as an epoxy, a resin, a moldable polymer, or the like. The molding compound 312 may be applied while substantially liquid, and then may be cured through a chemical reaction, such as in an epoxy or resin. In some other embodiments, the molding compound 312 may be an ultraviolet (UV) or thermally cured polymer applied as a gel or malleable solid capable of being disposed around the semiconductor die 132A, and then may be cured using a UV or thermally curing process. The molding compound 312 may be cured with a mold.

The RDL structure 366 is disposed on the active surface 102as of the semiconductor die 102A. In addition, the RDL structure 366 is disposed between the active surface 102as of the semiconductor die 102A and the backside surface 132bs of the second semiconductor die 132A along the direction 120 and electrically connected to the TV interconnects 314. As shown in FIG. 1A, the semiconductor die 132A is separated from the memory package 400 by the RDL structure 366. The molding compound 312 fills a space (not shown) between the RDL structures 316 and 366 and adjoins sidewalls of the semiconductor die 132A and adjacent surfaces of the RDL structures 316 and 366. The RDL structures 316 and 366 are in contact with opposite ends of the TV interconnects 314, respectively. In other word, the semiconductor die 132A and the TV interconnects 314 are sandwiched between the RDL structures 316 and 366. Pads 104 on the active surface 102as of the semiconductor die 102A are electrically connected to the RDL structure 366 using conductive structures 112. In some embodiments, the conductive structures 112 and 142 may comprise the same or similar materials and structures. In some embodiments, the RDL structure 366 is electrically connected to the semiconductor die 132A by the TV interconnects 132TV1 and 132TV2 of the semiconductor die 132A, the TV interconnects 314 and the RDL structure 316. Since the RDL structure 366 and the RDL structure 316 are respectively close to a top surface 300TS and a bottom surface 300BS of the fan-out package 300A, the RDL structure 366 and the RDL structure 316 may be also called a top RDL structure 366 and a bottom RDL structure 316.

In some embodiments, the RDL structure 366 includes one or more conductive traces 370 and one or more vias 368 disposed in one or more dielectric layers 367. In some embodiments, the material of the conductive traces 370 may be similar to the material of the conductive traces 320. The material of the vias 368 may be similar to the material of the vias 318. In addition, the material of the dielectric layers 367 may be similar to the material of the dielectric layers 317. It should be noted that the number of vias 368, the number of conductive traces 370 and the number of dielectric layers 367 shown in FIG. 1A are only an example and is not a limitation to the present disclosure.

As shown in FIG. 1A, the memory package 400 is disposed on the RDL structure 366 by a bonding process. In some embodiments, the memory package 400 comprises a dynamic random access memory (DRAM) package or another applicable memory package. In some embodiments, the memory package 400 includes a substrate 418, at least one semiconductor dies, for example, two semiconductor dies 402 and 404 that are stacked on the substrate 418, and conductive structures 422. In some embodiments, each of the semiconductor dies 402 and 404 comprises a dynamic random access memory (DRAM) die (e.g., a double data rate 4 (DDR4) DRAM die, a low-power DDR4 (LPDDR4) DRAM die), synchronous dynamic random access memory (SDRAM) die or the like) or another applicable memory die. In some other embodiments, the semiconductor dies 402 and 404 may comprise the same or different devices. In some embodiments, the memory package 400 also comprises one or more passive components (not illustrated), such as resistors, capacitors, inductors, the like, or a combination thereof.

In this embodiment, as shown in FIG. 1A, there are two semiconductor dies 402 and 404 mounted on the substrate 418 by a paste (not shown). The semiconductor dies 402 and 404 have corresponding pads 408 and 410 thereon, respectively. The pads 408 and 410 of the semiconductor dies 402 and 404 may be electrically connected to the substrate 418 using bonding wires 414 and 416, respectively. However, the number of stacked memory dies is not limited to the disclosed embodiment. Alternatively, the semiconductor dies 402 and 404 as shown in FIG. 1A can be arranged side by side and mounted on the substrate 418 by a paste (not shown). Alternatively, the semiconductor dies 402 and 404 may be fabricated by a flip-chip technology and electrically connected to the substrate 418 without using the bonding wires 414 and 416.

As shown in FIG. 1A, the substrate 418 may comprise circuits 428 and contact pads 420 and 430 disposed in one or more extra-low K (ELK) and/or ultra-low K (ULK) dielectric layers (not shown). The contact pads 420 are disposed on the tops of the circuits 428 close to the top surface (die-attach surface) of the substrate 418. In addition, the bonding wires 414 and 416 are electrically connected to the corresponding contact pads 420. The contact pads 430 are disposed on the bottoms of the circuits 428 close to the bottom surface (bump-attach surface) of the substrate 418. The contact pads 430 are electrically connected to the corresponding contact pads 420. In some embodiments, the bonding wires 414 and 416, the contact pads 420 and 430 and the circuits 428 include a conductive material, such as metals comprising copper, gold, silver, or other applicable metals.

As shown in FIG. 1A, the conductive structures 422 are disposed on the bottom surface of substrate 418 opposite the semiconductor dies 402 and 404. The conductive structures 422 are electrically connected to (or in contact with) the corresponding the contact pads 430 of the substrate 418 and the RDL structure 366. In some embodiments, the conductive structures 422 comprise a conductive ball structure such as a copper ball, a conductive bump structure such as a copper bump or a solder bump structure, or a conductive pillar structure such as a copper pillar structure.

In some embodiments, as shown in FIG. 1A, the molding material 412 covering the substrate 418, encapsulating the semiconductor dies 402 and 404 and the bonding wires 414 and 416. The top surface of the molding material 412 may serve as a top surface 400T of the memory package 400. In some embodiments, the molding materials 312 and 412 may comprise the same or similar materials and fabrication processes.

As shown in FIG. 1A, the molding compound 362 covers the RDL structure 366, the semiconductor die 102A and the memory package 400. The molding compound 362 surrounds the semiconductor die 102A and the memory package 400. The molding compound 362 adjoins the backside surfaces 102bs and sidewalls (not shown) of the semiconductor die 102A and the top surface 400TS and sidewalls (not shown) of the memory package 400. In addition, a top surface of the molding compound 362 forms a top surface 300TS of the fan-out package 300A of the semiconductor package assembly 500A. Furthermore, the top surface 400TS of the memory package 400 is close to the top surface 300TS of the semiconductor package assembly 500A. In some embodiments, the molding materials 312, 362 and 412 may comprise the same or similar materials and fabrication processes. In some embodiments, edges 312E of the molding compound 312 are leveled with corresponding edges 316E of the RDL structure 316 and corresponding edges 366E of the RDL structure 366. Edges 362E of the molding compound 362 are leveled with the corresponding edges 366E of the RDL structure 366. Therefore, the edges 312 of the molding compound 312, the edges 362E of the molding compound 362, the edges 316E of the RDL structure 316 and the edges 366E of the RDL structure 366 may collectively serve as package edges of the fan-out package 300A.

As shown in FIG. 1A, the fan-out package 300A may further include underfills (not shown) filling a gap (not shown) between the RDL structure 316 and the semiconductor die 132A, a gap (not shown) between the RDL structure 336 and the semiconductor die 102A and a gap (not shown) between the RDL structure 336 and the memory package 400. In some embodiments, the underfills surround portions of the conductive structures 112, 142 and 422 and are in contact with portions of the RDL structures 316 and 336 to further reduce the thermal resistance from the semiconductor die 132A to the RDL structure 316 and from the semiconductor die 102A and the memory package 400 to the RDL structure 366. In addition, the underfills may be disposed to compensate for differing coefficients of thermal expansion (CTEs) between the semiconductor dies 102A and 132A, the RDL structures 316 and 366 and the conductive structures 112, 142 and 422. In some embodiments, the underfill includes a capillary underfill (CUF), a molded underfill (MUF), or a combination thereof.

Since the semiconductor die 102A and the memory package 400 are side-by-side on the top RDL structure 366 of the fan-out package 300A, a thickness 362T of the molding compound 362 (measured from the top surface 300TS of the fan-out package 300A to an interface between the molding compound 362 and the top RDL structure 366) may depend primarily on a thickness 400T of the memory package 400. Therefore, a thickness 102T of the semiconductor die 102A can be increase to be the same of similar as the thickness 400T of the memory package 400 to improve the thermal performance (for example, the thicker thickness of the semiconductor die 102A primarily formed of silicon may improve thermal dissipation ability and the mismatch of thermal expansion of the coefficient (CTE) issue between the semiconductor die 102A and different materials in the semiconductor package assembly 500A).

As shown in FIG. 1A, the fan-out package 300A further includes an electronic component 330 mounted on the RDL structure 316 opposite the semiconductor die 132A. In some embodiments, the electronic component 330 has pads 332 on it and is electrically connected to the conductive traces 320 of the RDL structure 316. In some embodiments, the electronic component 330 is arranged between the conductive structures 322. The electronic component 330 can be free from being covered by a molding compound. In some embodiments, the electronic component 330 comprises integrated passive device (IPD) including a capacitor, an inductor, a resistor, or a combination thereof. In some embodiments, the electronic component 330 comprises DRAM dies.

As shown in FIGS. 1A-1C, the semiconductor die 102A and the semiconductor die 132A of the fan-out package 300A of the semiconductor package assembly 500A may include interfaces arranged on the edges of the semiconductor dies 102A and 132A. In some embodiments, the interfaces of the fan-out package 300A used herein may include circuitry and input/output connections (e.g. the pads 104 and 134) disposed on the active surface 102as of the semiconductor die 102A and the active surface 132as of the semiconductor die 132A. In some embodiments, the interfaces of the semiconductor dies 102A and 132A are used for signal (data) and power transmission and grounding paths between the different semiconductor dies 102A and 132A, between the semiconductor die 102A and the memory package 400 or between the semiconductor die 132A and the memory package 400. It is noted that FIGS. 1B and 1C only show the semiconductor dies 102A and 132A, the molding material 312/362 and the conductive structures 422 of the memory package 400 for illustration, the remaining features may be shown in the schematic cross-sectional views of FIG. 1A. It is appreciated that although some features are shown in some embodiments but not in other embodiments, these features may (or may not) exist in other embodiments whenever possible. For example, although each of the illustrated example embodiments shows specific arrangements of the interfaces of the semiconductor dies 102A and 132A and the conductive structures 422 of the memory package 400, any other combinations of the arrangements of the interfaces of the semiconductor dies 102A and 132A and the conductive structures 422 of the memory package 400 may also be used whenever applicable.

As shown in FIG. 1B, the semiconductor dies 102A and 132A may have a rectangular plan-view shape. The semiconductor die 102A may have opposite edges 102E1 and 102E3 extending substantially along the direction 110 and opposite edges 102E2 and 102E4 substantially along the direction 100. The semiconductor die 132A may have opposite edges 132E1 and 132E3 extending substantially along the direction 110 and opposite edges 132E2 and 132E4 substantially along the direction 100. The edge 102E1 of the semiconductor die 102A is close to the edge 132E3 of the semiconductor die 132A. The edge 102E2 of the semiconductor die 102A connected between (or adjacent to) the edges 102E1 and 102E3 is close to the edge 132E2 of the semiconductor die 132A connected between the edges 132E1 and 132E3. The edge 102E4 of the semiconductor die 102A connected between (or adjacent to) the edges 102E1 and 102E3 is close to the edge 132E4 of the semiconductor die 132A connected between the edges 132E1 and 132E3. The edge 102E3 of the semiconductor die 102A connected between the edges 102E2 and 102E4 is away from the edge 132E1 of the semiconductor die 132A connected between the edges 132E2 and 132E4.

In some embodiments, the top semiconductor die may be used to control the memory package and include various interfaces for the electrical connections with the bottom semiconductor dies and the memory package inside the fan-out package. The bottom semiconductor die fabricated with TV interconnects may only include an interface for the electrical connections with the top semiconductor die of the fan-out package. For example, the semiconductor die (the top semiconductor die) 102A may include interfaces 102DDR (including interfaces 102DDR-1, 102DDR-2, 102DDR-3, 102DDR-4) and 102DTD extending along the direction 110 and arranged side-by-side along the direction 100. The interfaces 102DDR are arranged on the edge 102E1 close to the memory package 400. The interface 102DTD is arranged adjacent to the interfaces 102DDR opposite the edge 102E1, so that the interfaces 102DDR are disposed between the interface 102DTD and the memory package 400 along the direction 100. In addition, the semiconductor die (the bottom semiconductor die) 132A having the TV interconnects 132TV1 and 132TV2 may include a single interface 132DTD arranged on the edge 132E3 and overlapping the interface 102DTD along the direction 120. When the semiconductor die 102A is a SOC die, the memory package 400 is a double data rate 4 (DDR4) DRAM package, the interfaces 102DDR-1, 102DDR-2, 102DDR-3, 102DDR-4 may be double data rate 4 (DDR4) interfaces used for control the memory package 400 (for example, transferring data to/from the memory controller in the semiconductor die 102A). In some embodiments, the interfaces 102DDR-1, 102DDR-2, 102DDR-3, 102DDR-4 are electrically connected to the memory package 400 by the RDL structure 366 rather than the RDL structure 316. In addition, the interface 102DTD of the semiconductor die 102A and the interface 132DTD of the semiconductor die 132A may be die-to-die (DTD) interfaces including any suitable direct conductive electrical coupling between two different semiconductor dies 102A and 132A for data transmission. In some embodiments, the TV interconnects 132TV1 are disposed within the interface 132DTD arranged on the semiconductor die 132A and electrically connected to the interface 102DTD arranged on the semiconductor die 102A by the RDL structure 366 rather than the interfaces 102DDR-1, 102DDR-2, 102DDR-3 and 102DDR-4. In some embodiments, the TV interconnects 132TV2 may be disposed within other interfaces (not shown) of the semiconductor die 132A overlapping the interfaces 102DDR of the semiconductor die 102A. The TV interconnects 132TV2 are electrically connected to the interfaces 102DDR of the semiconductor die 102A by the RDL structure 366 to provide additional power transmission and grounding paths form the interfaces 102DDR to the base 200.

In some embodiments, the conductive structures 422 of the memory package 400 (e.g. the DDR4 DRAM package) are arranged according the given arrangement. For example, the conductive structures 422 of the memory package 400 are arranged in two groups 422G1 and 422G2 (including a single column or multi-columns of the conductive structures 422) along the direction 100, as shown in FIG. 1B. Each group 422G1 and 422G2 of the conductive structures 422 may provide two data channels for the conductive structures 422. In order to reduce the length of routing paths between the top package 400 and the bottom package 300, the interfaces 102DDR-1, 102DDR-2, 102DDR-3, 102DDR-4 of the semiconductor die 102A may be arranged corresponding to the arrangement of the conductive structures 422 of the memory package 400. Since the semiconductor die 102A including the interfaces 102DDR and the memory package 400 are in a side-by-side arrangement without any RDL structure interposed between, the interfaces 102DDR-1, 102DDR-2 of the semiconductor die 102A may be arranged close to the group 422G1 of the conductive structures 422. The interfaces 102DDR-3 and 102DDR-4 of the semiconductor die 102A may be arranged close to the group 422G2 of the conductive structures 422, as shown in FIG. 1B.

According to the arrangements of the interfaces 102DDR and 102DTD of the semiconductor die 102A and the interface 132DTD and the TV interconnects 132TV1 and 132TV2 of the semiconductor die 132A, the memory package 400 is electrically connected to the semiconductor die 102A by the conductive structures 422, the interfaces 102DDR and the RDL structure 366 rather than the TV interconnects 314 and the RDL structure 316 for signal transmission. In addition, the interfaces 102DTD and 132DTD are electrically connected to the base 200 by the conductive structures 422, the interfaces 102DDR, the RDL structures 316 and 366 and the TV interconnects 132TV2 for power transmission and grounding. The RDL structure 366 is electrically connected to the interfaces 102DDR, 102DTD and 132DTD and the TV interconnects 132TV1 and 132TV2. Therefore, the memory package 400 may be electrically connected to the semiconductor die 132A by the conductive structures 422, the interfaces 102DDR, 102DTD and 132DTD, the RDL structure 366 and the TV interconnects 132TV1 rather than the TV interconnects 314 and the RDL structure 316.

In some embodiments, the interfaces 102DDR may be arranged on three adjacent edges of the semiconductor die 102A. As shown in FIG. 1C, an interface 102DDR-1′ of the semiconductor die 102A may be arranged on the edge 102E4 connected to the edges 102E1 and 102E3 and opposite the edge 102E2. In addition, an interface 102DDR-4′ of the semiconductor die 102A may be arranged on the edge 102E2 connected to the edges 102E1 and 102E3 and opposite the edge 102E4. The memory package 400 is electrically connected to the semiconductor die 102A by the interfaces 102DDR-1′, 102DDR-2, 102DDR-3 and 102DDR-4′. According to the arrangements of the interfaces 102DDR-1′ and 102DDR-4′, the flexibility of the floorplan design (including interface and/or routing design) of the semiconductor die 102A for the channel arrangements of the memory package 400 can be increased.

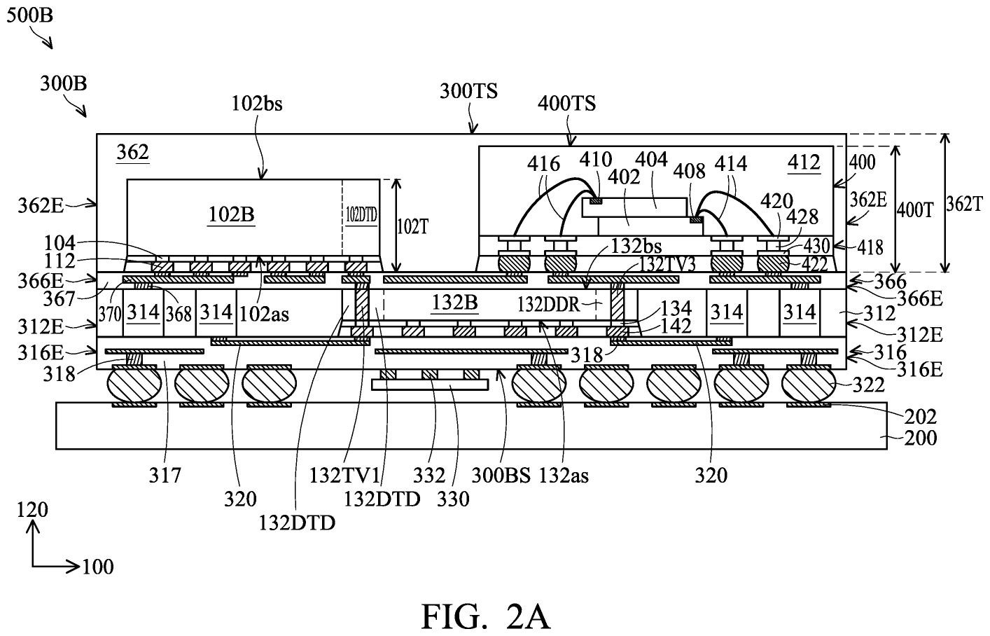

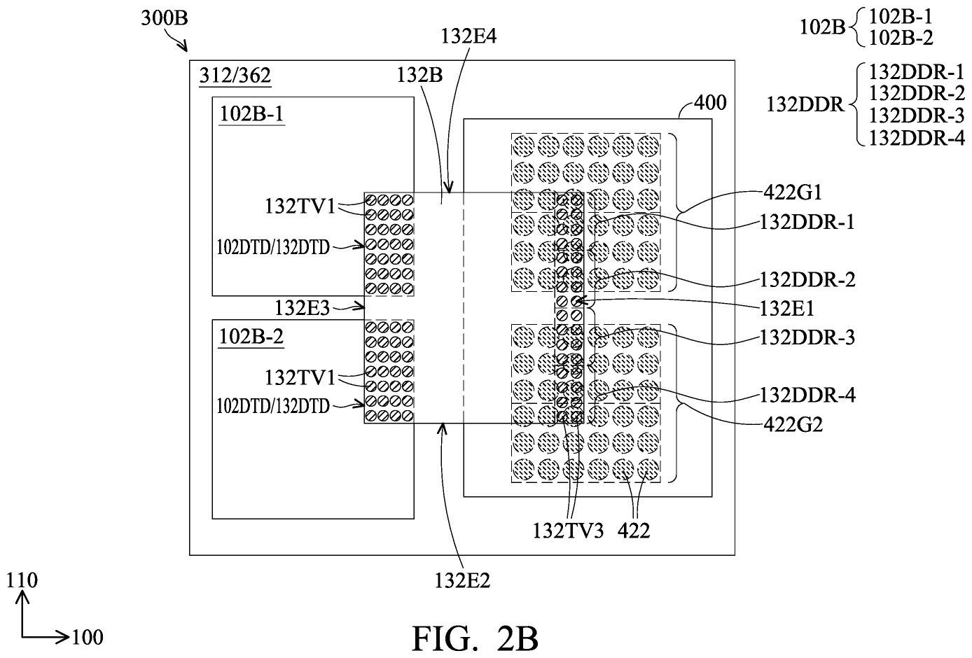

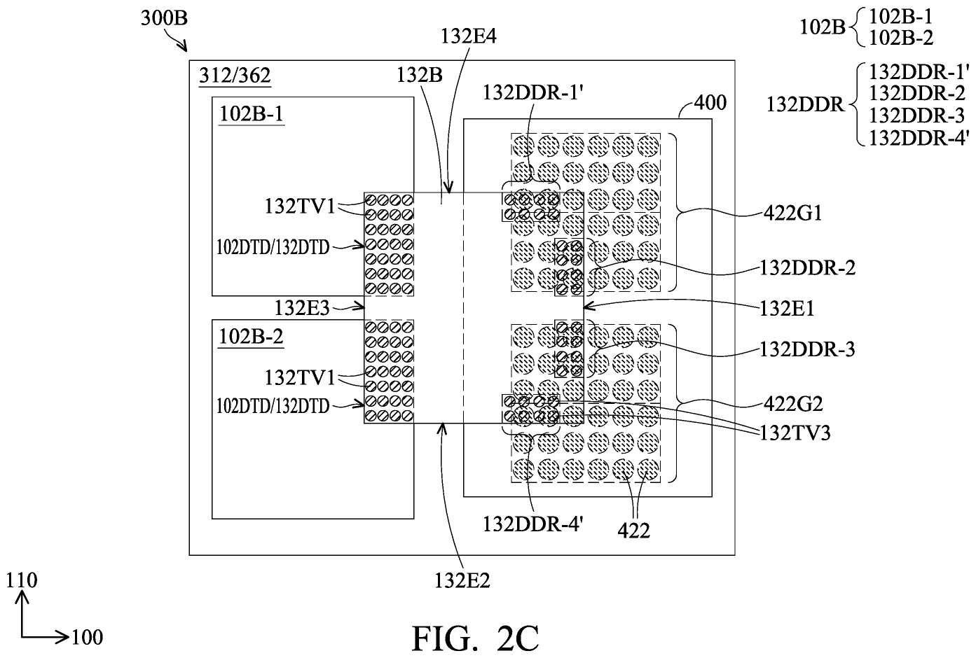

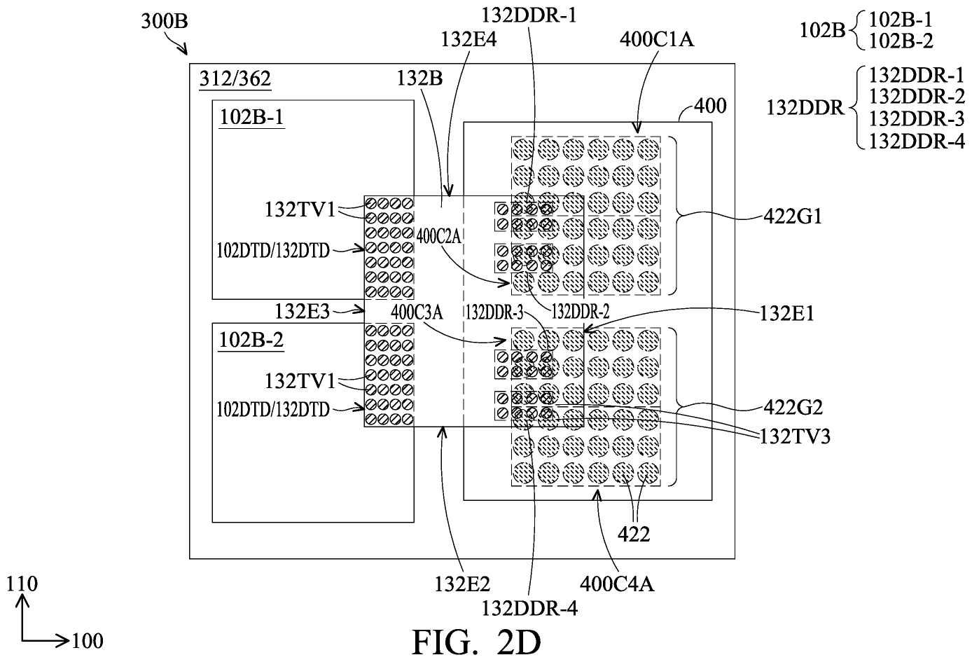

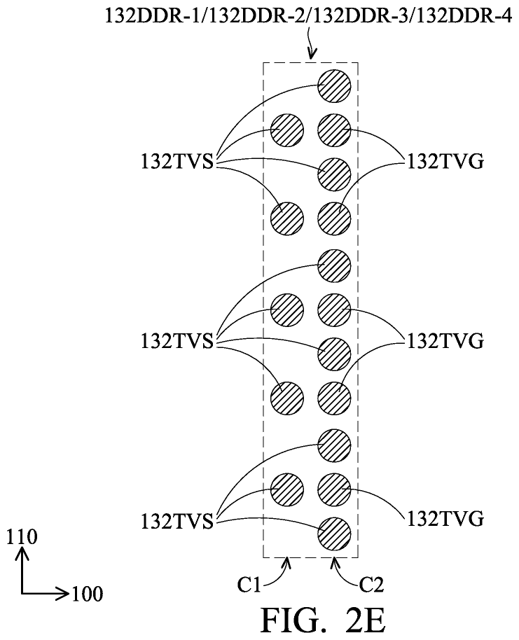

In some embodiments, the bottom semiconductor die fabricated with the TV interconnects may include various interfaces for the electrical connections with the top semiconductor die and the memory package inside the fan-out package. The top semiconductor die may only include the interface for the electrical connections with the top semiconductor die of the fan-out package. Therefore, the top semiconductor die may control the memory package by the bottom semiconductor die. FIG. 2A is a cross-sectional view of a semiconductor package assembly 500B in accordance with some embodiments of the disclosure. FIGS. 2B, 2C and 2D are perspective bottom views (plan views) of a fan-out package 300B of the semiconductor package assembly 500B of FIG. 2A in accordance with some embodiments of the disclosure, showing the arrangement of the interfaces of semiconductor dies 102B and 132B and the through via (TV) interconnects 132TV1 and 132TV3 of the semiconductor die 132B. Elements of the embodiments hereinafter, that are the same or similar as those previously described with reference to FIGS. 1A-1C, are not repeated for brevity.

As shown in FIGS. 2A and 2B, the fan-out package 300B may include one or more semiconductor dies 102B. For example, the fan-out package 300B may include semiconductor dies 102B-1 and 102B-2 each including only one type of the interfaces such as the interface 102DTD. The semiconductor die 102B-1 (or the semiconductor die 102B-2) and the memory package 400 are arranged side-by-side along the direction 100. The semiconductor die dies 102B-1 and 102B-2 and the memory package 400 are stacked on the semiconductor die 132B including various interfaces 132DDR (including interfaces 132DDR-1, 132DDR-2, 132DDR-3 and 132DDR-4 shown in FIG. 2B) and 132DTD and the TV interconnects 132TV1 and 132TV3 along the direction 120 that is different from the direction 100. In other word, the semiconductor die 132B is arranged beside the semiconductor die dies 102B-1 and 102B-2 and the memory package 400 along the direction 120. In some embodiments, the interfaces 132DDR are arranged on the edge 132E1 of the semiconductor die 132B and overlapping the memory package 400 along the direction 120. The memory package 400 is electrically connected to the semiconductor die 132B by the interfaces 132DDR and the RDL structure 366. The interfaces 132DTD are arranged on the edge 132E3 opposite the edge 132E1 of the semiconductor die 132B. In addition, the interfaces 132DTD are arranged overlapping the corresponding interfaces 102DTD of the semiconductor dies 102B-1 and 102B-2 along the direction 120.

As shown in FIGS. 2A and 2B, the TV interconnects 132TV1 of the semiconductor die 132B are disposed within the interfaces 132DTD and electrically connected to the interfaces 102DTD of the semiconductor dies 102B-1 and 102B-2. In addition, the semiconductor die 132B may further include the TV interconnects 132TV3 disposed within the interfaces 132DDR and electrically connected to the memory package 400. In some embodiments, the TV interconnects 132TV1, 132TV2 (FIG. 1A) and 132TV3 may comprise the same or similar materials and structures.

Since the semiconductor die 132B including the interfaces 132DDR and the memory package 400 are in an overlapping arrangement with the RDL structure 366 interposed between, the interfaces 132DDR-1 and 132DDR-2 of the semiconductor die 132B may be arranged overlapping the group 422G1 of the conductive structures 422. In addition, the interfaces 132DDR-3 and 132DDR-4 of the semiconductor die 132B may be arranged overlapping the group 422G2 of the conductive structures 422, as shown in FIG. 2B.

According to the arrangements of the interfaces 132DDR and the TV interconnects 132TV3 of the semiconductor die 132B, the memory package 400 is electrically connected to the semiconductor die 132B with a shorten routing path for data transmission. In addition, the TV interconnects 132TV3 within the interfaces 132DDR may be electrically connected to the conductive structures 322 by the conductive structures 142 for power transmission and grounding without passing other interfaces on the semiconductor die 132B.

In some embodiments, the interfaces 132DDR may be arranged on three adjacent edges of the semiconductor die 132B. As shown in FIG. 2C, an interface 132DDR-1′ of the semiconductor die 132B may be arranged on the edge 132E4 connected to the edges 132E1 and 132E3 and opposite the edge 132E2. In addition, an interface 132DDR-4′ of the semiconductor die 132B may be arranged on the edge 132E2 connected to the edges 132E1 and 132E3 and opposite the edge 132E4. The memory package 400 is electrically connected to the semiconductor die 132B by the interfaces 132DDR-1′, 132DDR-2, 132DDR-3 and 132DDR-4′. According to the arrangements of the interfaces 132DDR-1′ and 132DDR-4′, the flexibility of the floorplan design (including interface and/or routing design) of the semiconductor die 132B for the channel arrangements of the memory package 400 can be increased.

In some embodiments, the orientation and shape of the distribution area and the sequence of the pin assignment of the TV interconnects 132TV3 within the interfaces 132DDR of the semiconductor die 132B may be the same or similar as those of the conductive structures 422 of the memory package 400 overlapping the interfaces 132DDR to shorten the routing path (between the interfaces 132DDR and the conductive structures 422) for data transmission. In a plan view as shown in FIG. 2D, the TV interconnects 132TV3 disposed within the interfaces 132DDR-1, 132DDR-2, 132DDR-3 and 132DDR-4 may have distribution areas 132DDR-1A, 132DDR-2A, 132DDR-3A and 132DDR-4A. The conductive structures 422 arranged in the two data channels of the group 422G1 may have distribution areas 422C 1A and 422C2A. In addition, the conductive structures 422 arranged in the two data channels of the group 422G2 may have distribution areas 422C3A and 422C4A. In some embodiments, the distribution areas 132DDR-1A, 132DDR-2A, 132DDR-3A and 132DDR-4A of the TV interconnects 132TV3 corresponds to and at least partially overlaps the distribution areas 422C1A, 422C2A, 422C3A and 422C4A of the conductive structures 422.

In some embodiments, the ground TV interconnects and signal TV interconnects within the DDR interfaces may have an interleaved arrangement. Each ground TV interconnect is interposed between the two adjacent signal TV interconnects in order to reduce cross-talk noise from adjacent signal TV interconnects. FIG. 2E is an enlarge plan view of the semiconductor die 132B of the fan-out package 500B of the semiconductor package assembly 500B of FIG. 2A in accordance with some embodiments of the disclosure, showing the arrangement of the TV interconnects within the interfaces 132DDR-1, 132DDR-2, 132DDR-3 and 132DDR-4 of the semiconductor die (the bottom semiconductor die) 132B. Elements of the embodiments hereinafter, that are the same or similar as those previously described with reference to FIGS. 1A-1C and 2A-2D, are not repeated for brevity. It is noted that FIG. 2E only shows ground TV interconnects 132TVG and signal TV interconnects 132TVS within the interfaces 132DDR-1, 132DDR-2, 132DDR-3 and 132DDR-4 for illustration, the power TV interconnects are hidden in the figure. As shown in FIG. 2E, the TV interconnects (such as the TV interconnects TV3 shown in FIGS. 2A-2B) within the interfaces 132DDR-1, 132DDR-2, 132DDR-3 and 132DDR-4 may include the signal TV interconnects 132TVS and the ground TV interconnects 132TVG arranged in multi-columns, for example, in two columns C1 and C2. In some embodiments, the ground TV interconnects 132TVG are designed to be arranged only in the column C1. The signal TV interconnects 132TVS are arranged in the columns C1 and C2. In some embodiments, the signal TV interconnects 132TVS in the column C1 are designed to be interleaved with the ground TV interconnects 132TVG. In addition, the signal TV interconnects in the column C2 are designed to be adjacent to the ground TV interconnects 132TVG in the column C1.

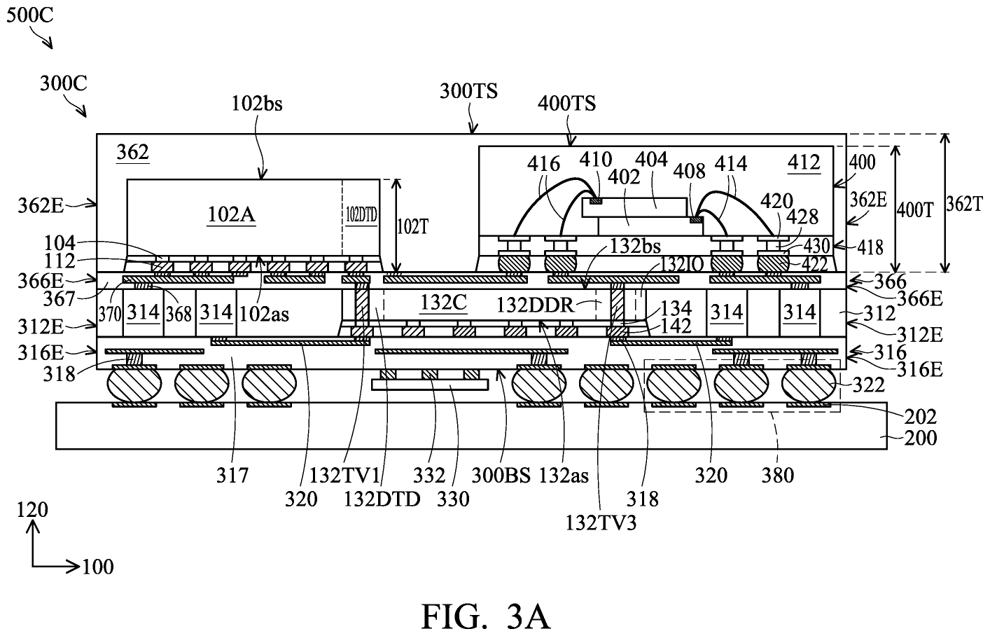

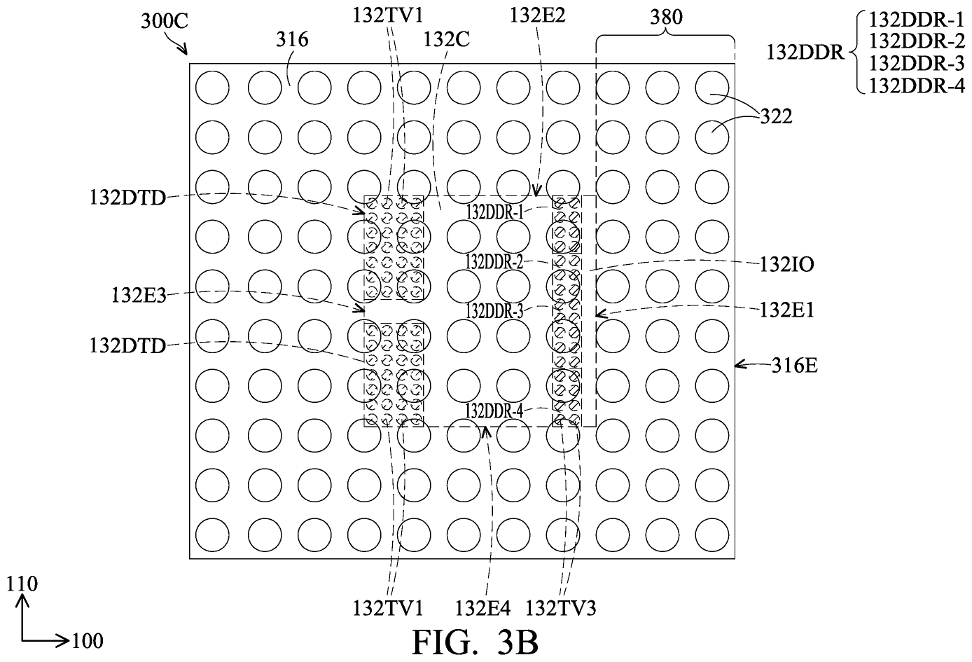

In some embodiments, the bottom semiconductor die may further include an additional interface (also called digital input/output (I/O) interface) to transmit digital input/output (I/O) signals to control other external integrated circuits (ICs) connected to the base. The digital I/O interface may be arranged adjacent to the DDR4 interfaces and close to the edge of the bottom semiconductor die to facilitate the utilization of the conductive structures between the DDR4 interfaces and the corresponding package edge of the fan-out package. FIG. 3A is a cross-sectional view of a semiconductor package assembly 500C in accordance with some embodiments of the disclosure. FIG. 3B is a perspective plan view (the bottom view) of a fan-out package 300C of the semiconductor package assembly 500C of FIG. 3A in accordance with some embodiments of the disclosure, showing the arrangement of an interface 13210 of a semiconductor die 132C and the conductive structures 322 excepting for the interfaces 132DDR-1, 132DDR-2, 132DDR-3 and 132DDR-4 and 132DTD. It is noted that FIG. 3B only shows the TV interconnects 132TV1 within the interfaces 132DTD and 132DTD 132TV3 within the interfaces 132DDR-1, 132DDR-2, 132DDR-3 and 132DDR-4 for illustration, the 102B 400 and 422 are hidden in the figure. Elements of the embodiments hereinafter, that are the same or similar as those previously described with reference to FIGS. 1A-1C and 2A-2E, are not repeated for brevity.

As shown in FIGS. 3A and 3B, the difference between the semiconductor package assembly 500B and the semiconductor package assembly 500C is that the semiconductor die 132C of the fan-out package 300C of the semiconductor package assembly 500C may further include the interface 13210 to transmit digital input/output (I/O) signals to control other external ICs (not shown) connected to the base 200. The interface 13210 may be arranged adjacent to the interfaces 132DDR-1, 132DDR-2, 132DDR-3 and 132DDR-4 and closer to the edge 132E1 than the interfaces 132DDR-1, 132DDR-2, 132DDR-3 and 132DDR-4. In other words, the interfaces 132DDR-1, 132DDR-2, 132DDR-3 and 132DDR-4 are arranged close to the edge 132E1 and between the interfaces 132DTD and the interface 13210 along the direction 100. In some embodiments, the interface 13210 is electrically connected to the conductive structures 322 in a region 380 outside the edge 132E1 along the direction 100 by the RDL structure 316 rather than the RDL structure 366, as shown in FIG. 3B. In addition, the region 380 is positioned between the edge 132E1 and the corresponding edge 316E of the RDL structure 316 (also called the package edge 316E of the semiconductor package assembly 500C). Therefore, the utilization of the conductive structures 322 outside the interfaces 132DDR-1, 132DDR-2, 132DDR-3 and 132DDR-4 is improved.

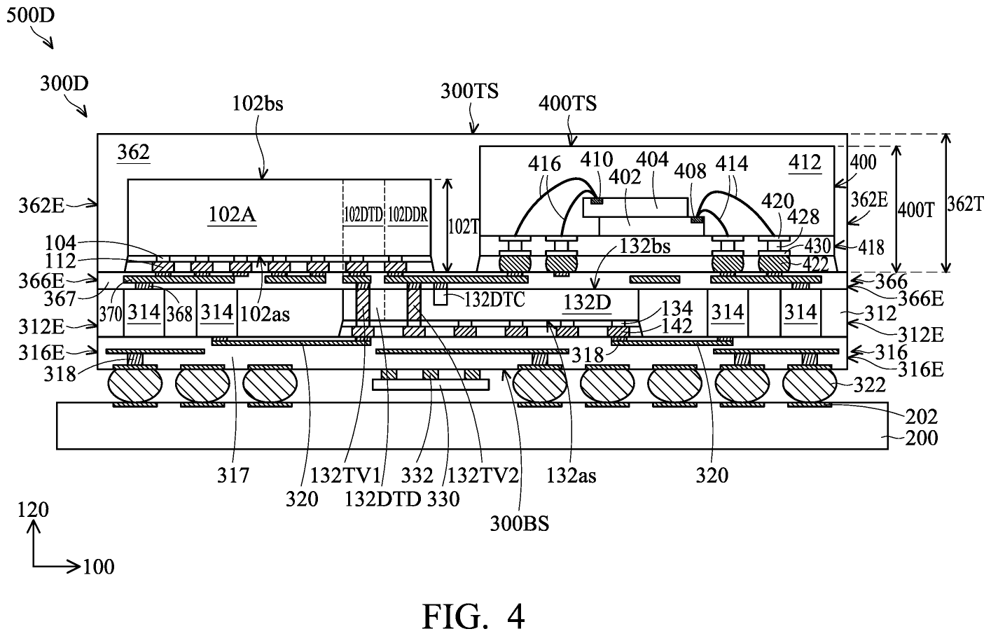

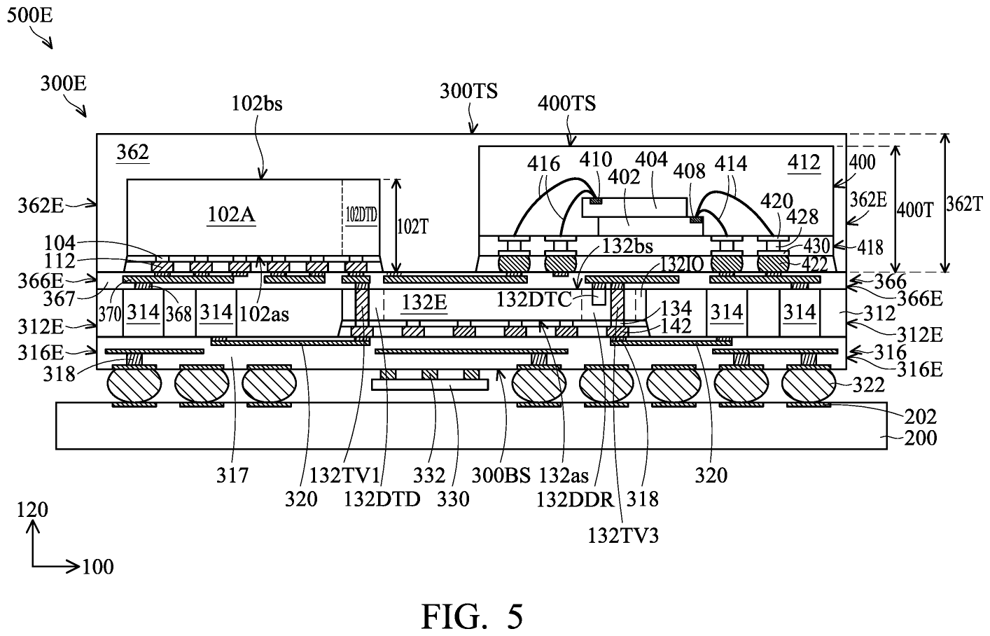

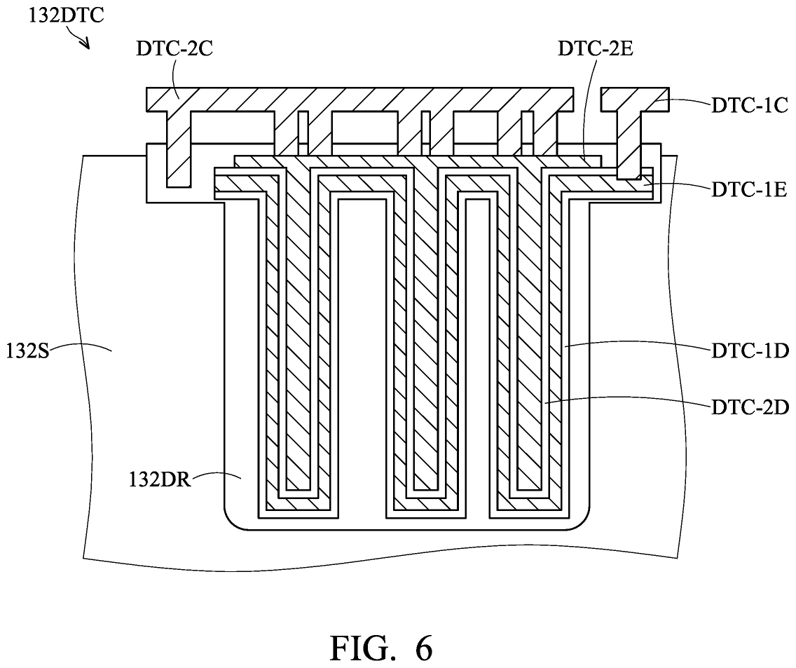

In some embodiments, the bottom semiconductor die may further include an embedded trench capacitor (such as a deep trench capacitor (DTC)) to provide higher capacitance for the memory package 400 than the conventional on-die capacitor. FIG. 4 is a cross-sectional view of a semiconductor package assembly 500D in accordance with some embodiments of the disclosure. FIG. 5 is a cross-sectional view of a semiconductor package assembly 500E in accordance with some embodiments of the disclosure. FIG. 6 is an enlarge cross-sectional view of the semiconductor package assembly 500D or 500E in accordance with some embodiments of the disclosure showing a trench capacitor 132DTC embedded in a semiconductor die 132D or 132E of a fan-out package 300D or 300E of the semiconductor package assembly 500D or 500E of FIGS. 4 and 5. Elements of the embodiments hereinafter, that are the same or similar as those previously described with reference to FIGS. 1A-1C, 2A-2E and 3A-3B, are not repeated for brevity.

As shown in FIG. 4, the difference between the semiconductor die 132A of the semiconductor package assembly 500A and a semiconductor die 132D of the semiconductor package assembly 500D is that the semiconductor die 132D includes a trench capacitor 132DTC embedded in the semiconductor die 132D. In some embodiments, the trench capacitor 132DTC is disposed within a region of the semiconductor die 132D overlapping the interfaces 102DDR of the semiconductor die 102A. In addition, the trench capacitor 132DTC may be arranged adjacent to the TV interconnects 132TV2. In some embodiments, the trench capacitor 132DTC may be electrically connected to the memory package 400 by the RDL structure (the top RDL structure) 366 and the interfaces 102DDR-1, 102DDR-2, 102DDR-3 and 102DDR-4 of the semiconductor die (the top semiconductor die) 102A.

As shown in FIG. 5, the difference between the semiconductor die 132B of the semiconductor package assembly 500B and a semiconductor die 132E of the semiconductor package assembly 500E is that the semiconductor die 132E includes the trench capacitor 132DTC embedded in the semiconductor die 132E. In some embodiments, the trench capacitor 132DTC is disposed within at least one of the interfaces 132DDR-1, 132DDR-2, 132DDR-3 and 132DDR-4 and electrically connected to the memory package 400 by the RDL structure 366. In addition, the trench capacitor 132DTC may be arranged adjacent to the TV interconnects 132TV3.

As shown in FIG. 6, the trench capacitor 132DTC may be formed from a silicon substrate 132S of the semiconductor die 132D (or the semiconductor die 132E) and formed by the semiconductor processes. The trench capacitor 132DTC may be formed in a trench (not shown) in a doped region 132DR of the silicon substrate 132S and separated from the silicon substrate 132S by a dielectric layer DTC-1D for isolation. In addition, the conductivity of the doped region 132DR may be different from that of doped region 132DR. In some embodiments, the trench capacitor 132DTC may include a first electrode DTC-1E, a dielectric layer DTC-2D, a second electrode DTC-2E, a first electrode contact DTC-1C and a second electrode contact DTC-2C. The first electrode DTC-1E and the second electrode DTC-2E formed of doped silicon, poly or conductive materials are conformally formed in the trench. In addition the dielectric layer DTC-2D is sandwiched between the first electrode DTC-1E and the second electrode DTC-2E. The first electrode contact DTC-1C is disposed on and electrically connected to the first electrode DTC-1E. The second electrode contact DTC-2C is disposed on and electrically connected to the second electrode DTC-2E. In some embodiments, the second electrode contact DTC-2C may be further electrically connected to the doped region 132DR to increase the capacitance. In some embodiments, the first electrode contact DTC-1C and the second electrode contact DTC-2C may be a portion of the RDL structure 366 and composed of the conductive traces 370 and the vias 368 (as show in FIGS. 4 and 5).

Embodiments provide a semiconductor package assembly, the semiconductor package assembly includes a fan-out package including a top semiconductor die (e.g., a SoC die), a bottom semiconductor die and a memory package stacked on each other and mounted on a base. The top semiconductor die and the memory package are arranged side-by-side along a lateral direction (e.g. the direction 100) and both stacked on the bottom semiconductor die having the through via (TV) interconnects along a vertical direction (e.g. the direction 120). Therefore, the top semiconductor die may be fabricated in a thicker thickness (for example, the thickness of the top semiconductor die may be similar as that of the memory package) to improve the thermal performance. In some embodiments, the top semiconductor die includes a first interface (e.g., die-to-die (DTD) interfaces) overlapping and electrically connected to a second interface (e.g., the DTD interface) arranged on the bottom semiconductor die and a third interface (e.g., DDR4 interfaces) used for control the memory package. The third interface is arranged adjacent to the first interface and on one or more adjacent edges of the top semiconductor die close to the memory package. The third interface is electrically connected to the memory package by the top RDL structure vertically between the top semiconductor die and the bottom semiconductor die for signal transmission. In addition, the third interface of the top semiconductor die may be electrically connected to the base by the TV interconnects passing through other interfaces of the bottom semiconductor die for power transmission and grounding. In some embodiments, the third interface used for control the memory package is arranged on the bottom semiconductor die. Therefore, the third interface of the bottom semiconductor die may overlap the memory package along the vertical direction. In addition, the third interface of the bottom semiconductor die may include the TV interconnects disposed within for data and power transmission and grounding. Therefore, the length of the routing paths between the third interface of the bottom semiconductor die memory package and the size of the semiconductor package assembly can be further reduced. In some embodiments, the ground and signal TV interconnects within the third interfaces may have an interleaved arrangement. Each ground TV interconnect may act as shielding between the two adjacent signal TV interconnects, so that signal integrity issues such as crosstalk noise and delay uncertainty can be improved upon. In some embodiments, the orientation and shape of the distribution area and the sequence of the pin assignment of the TV interconnects within the third interface of the bottom semiconductor die may be the same or similar as those of the overlapping conductive structures of the memory package to shorten the routing path (between the third interface and the conductive structures of the memory package) for data transmission. In some embodiments, the bottom semiconductor die may further include an additional digital input/output (I/O) interface adjacent to the third interface to transmit digital input/output (I/O) signals to control other external ICs by the base. Therefore, the utilization of the conductive structures of the fan-out package in the region outside the third interface can be further improved. In some embodiments, the bottom semiconductor die may further include trench capacitors to provide higher capacitance for the memory package than the conventional on-die capacitor.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package assembly, comprising:
a first semiconductor die and a second semiconductor die stacked on each other, wherein the first semiconductor die comprises:
a first interface overlapping and electrically connected to a second interface arranged on the second semiconductor die; and
a third interface arranged on a first edge of the first semiconductor die; and
a memory package beside the first semiconductor die, wherein the memory package is electrically connected to the first semiconductor die by the third interface.

2. The semiconductor package assembly as claimed in claim 1, wherein the first semiconductor die has a first critical dimension and the second semiconductor die has a second critical dimension, wherein the first critical dimension is narrower than the second critical dimension.

3. The semiconductor package assembly as claimed in claim 1, wherein the first semiconductor die comprises a fourth interface arranged on a second edge of the first semiconductor die and connected to the first edge, wherein the memory package is electrically connected to the first semiconductor die and the second semiconductor die by the fourth interface.

4. The semiconductor package assembly as claimed in claim 1, wherein the first semiconductor die and the memory package are arranged side-by-side along a first direction, and wherein the first semiconductor die is stacked on the second semiconductor die along a second direction that is different from the first direction.

5. The semiconductor package assembly as claimed in claim 4, wherein the third interface is arranged adjacent to the first interface and between the first interface and the memory package along the first direction.

6. The semiconductor package assembly as claimed in claim 4, wherein the second semiconductor die comprises:
first through via (TV) interconnects disposed in the second semiconductor die overlapping and electrically connected to the third interface of the first semiconductor die; and
second TV interconnects disposed within the second interface and electrically connected to the first interface of the first semiconductor die.

7. The semiconductor package assembly as claimed in claim 6, wherein the second semiconductor die comprises a trench capacitor embedded in the second semiconductor die and electrically connected to the memory package by the third interface of the first semiconductor die.

8. The semiconductor package assembly as claimed in claim 1, wherein the second semiconductor die and the memory package are arranged side-by-side along a first direction, and wherein the second semiconductor die and the memory package are stacked on the first semiconductor die along a second direction that is different from the first direction.

9. The semiconductor package assembly as claimed in claim 8, wherein the third interface is arranged overlapping the memory package along the second direction.

10. The semiconductor package assembly as claimed in claim 8, wherein the first interface is arranged on a third edge of the first semiconductor die and opposite the first edge.

11. The semiconductor package assembly as claimed in claim 8, wherein the first semiconductor die comprises:
third through via (TV) interconnects disposed within the third interface and electrically connected to the memory package; and
fourth TV interconnects disposed within the first interface and electrically connected to the second interface of the second semiconductor die.

12. The semiconductor package assembly as claimed in claim 11, wherein the memory package comprises first conductive structures arranged in a group and having a first distribution area, the third TV interconnects have a second distribution area corresponding to and at least partially overlapping the first distribution area.

13. The semiconductor package assembly as claimed in claim 8, wherein the third TV interconnects are arranged in a first column and a second column adjacent to the first column and comprise:
ground TV interconnects arranged only in the first column; and
signal TV interconnects arranged in the first column and the second column, wherein the signal TV interconnects in the first column are interleaved with the ground TV interconnects, and the signal TV interconnects in the second column are adjacent to the ground TV interconnects.

14. The semiconductor package assembly as claimed in claim 8, wherein the first semiconductor die comprises a trench capacitor embedded within the third interface and electrically connected to the memory package.

15. The semiconductor package assembly as claimed in claim 1, further comprising:
a fan-out package comprising the first semiconductor die, the second semiconductor die and the memory package, wherein the fan-out package further comprises:
a first redistribution layer (RDL) structure disposed between the first semiconductor die and the second semiconductor die, wherein the first RDL structure is electrically connected to the first interface, the second interface, the third interface and the memory package;
a second redistribution layer (RDL) structure electrically connected to the first RDL structure and separated from the memory package by the first RDL structure;
a first molding compound covering the first RDL structure and the memory package;
a second molding compound filling a space between the first RDL structure and the second RDL structure;
a fifth TV interconnect passing through the second molding compound and electrically connected to the first RDL structure and the second RDL structure; and
second conductive structures in contact with and electrically connected to the second RDL structure.

16. The semiconductor package assembly as claimed in claim 15, wherein the first semiconductor die comprises a fifth interface arranged adjacent to the third interface and closer to the first edge than the third interface.

17. The semiconductor package assembly as claimed in claim 16, wherein the fifth interface is electrically connected to the second conductive structures outside the first edge by the second RDL structure rather than the first RDL structure.

18. A semiconductor package assembly, comprising:
a fan-out package, comprising:
a memory package;
a first semiconductor die arranged beside the memory package along a first direction; and
a second semiconductor die arranged beside the memory package along
a second direction, wherein the first semiconductor die comprises:
a first interface overlapping and electrically connected to a second interface arranged on the second semiconductor die; and
a third interface arranged close to and electrically connected to the memory package.

19. The semiconductor package assembly as claimed in claim 18, wherein the first semiconductor die comprises a fourth interface, wherein the third interface and the four interface are arranged on adjacent edges of the first semiconductor die, wherein the memory package is electrically connected to the first semiconductor die by the fourth interface.

20. The semiconductor package assembly as claimed in claim 18, further comprising:
a first redistribution layer (RDL) structure disposed between the first semiconductor die and the second semiconductor die, wherein the first RDL structure is electrically connected to the first interface, the second interface, the third interface and the memory package; and
a second redistribution layer (RDL) structure electrically connected to the first RDL structure and separated from the memory package by the first RDL structure.

21. The semiconductor package assembly as claimed in claim 20, wherein the first semiconductor die is disposed between the first RDL structure and the second RDL structure and comprises through via (TV) interconnects disposed within the first interface and the third interface.

22. The semiconductor package assembly as claimed in claim 21, wherein the memory package comprises first conductive structures arranged in a group and having a first distribution area, and the TV interconnects arranged within the third interface having a second distribution area that correspond to and at least partially overlap the first distribution area.

23. The semiconductor package assembly as claimed in claim 21, wherein the TV interconnects disposed within the third interface are arranged in a first column and a second column adjacent to the first column and comprising:
ground TV interconnects arranged only in the first column; and
signal TV interconnects arranged in the first column and the second column, wherein the signal TV interconnects in the first column are interleaved with the ground TV interconnects, and the signal TV interconnects in the second column are adjacent to the ground TV interconnects.

24. The semiconductor package assembly as claimed in claim 21, wherein the first semiconductor die comprises a fifth interface arranged adjacent to the third interface and on a first edge of the first semiconductor die, so that the third interface is arranged between the first interface and the fifth interface along the second direction.

25. The semiconductor package assembly as claimed in claim 24, wherein the fifth interface is electrically connected to second conductive structures in contact with and electrically connected to the second RDL structure and outside the first edge by the second RDL structure rather than the first RDL structure.

26. The semiconductor package assembly as claimed in claim 21, wherein the first semiconductor die comprises a trench capacitor embedded within the third interface and electrically connected to the memory package by the first RDL structure.

27. The semiconductor package assembly as claimed in claim 18, wherein the second semiconductor die is disposed between the first RDL structure and the second RDL structure and comprises through via (TV) interconnects overlapping the first interface and the third interface of the first semiconductor die.

28. The semiconductor package assembly as claimed in claim 27, wherein the second semiconductor die comprises a trench capacitor embedded in the second semiconductor die, wherein the trench capacitor overlaps the third interface and is electrically connected to the memory package.

29. A semiconductor package assembly, comprising:
a fan-out package, comprising:
a first redistribution layer (RDL) structure and a second redistribution layer (RDL) structure stacked on each other;
a top semiconductor die and a memory package disposed on the first redistribution layer (RDL) structure, wherein the top semiconductor die comprises a first interface; and
a bottom semiconductor die disposed between the first RDL structure and the second RDL structure, wherein the bottom semiconductor die comprises:
a second interface overlapping the first interface; and
first through via (TV) interconnects arranged within the second interface and electrically connected to the first interface by the first RDL structure, and
wherein the memory package is electrically connected to the top semiconductor die and the bottom semiconductor die by the first RDL structure rather than the second RDL structure.

30. The semiconductor package assembly as claimed in claim 29, wherein the top semiconductor die comprises a third interface beside the first interface and close to the memory package, wherein the memory package is electrically connected to the top semiconductor die by the third interface.

31. The semiconductor package assembly as claimed in claim 30, wherein the bottom semiconductor die comprises second through via (TV) interconnects overlapping the third interface and electrically connected to the third interface by the first RDL structure.

32. The semiconductor package assembly as claimed in claim 29, wherein the bottom semiconductor die comprises a fourth interface overlapping the memory package, wherein the memory package is electrically connected to the bottom semiconductor die by the fourth interface.

33. The semiconductor package assembly as claimed in claim 32, wherein the bottom semiconductor die comprises a fifth interface arranged adjacent to the fourth interface and on a first edge of the bottom semiconductor die, so that the fourth interface is disposed between the second interface and the fifth interface.

34. The semiconductor package assembly as claimed in claim 32, wherein the bottom semiconductor die comprises third through via (TV) interconnects arranged within the fourth interface and electrically connected to the memory package.

35. The semiconductor package assembly as claimed in claim 34, wherein the third TV interconnects are arranged in a first column and a second column adjacent to the first column and comprises:
ground TV interconnects arranged only in the first column; and
signal TV interconnects arranged in the first column and the second column, wherein the signal TV interconnects in the first column are interleaved with the ground TV interconnects, and the signal TV interconnects in the second column are adjacent to the ground TV interconnects.

36. The semiconductor package assembly as claimed in claim 29, wherein the bottom semiconductor die comprises a trench capacitor embedded in the bottom semiconductor die and electrically connected to the memory package.
